(19) United States
(12) Patent Application Publication
(10) Pub. No.: US 2026/0160865 A1
(43) Pub. Date: Jun. 11, 2026

(54) HIGH RESOLUTION SPAD ARRAY FOR LIDAR USING MICROASSEMBLY PROCESS

(71) Applicant: GM GLOBAL TECHNOLOGY OPERATIONS LLC, Detroit, MI (US)

(72) Inventors: James FORESI, Bloomfield Hills, MI (US); Julien P. Mourou, Bloomfield Hills, MI (US)

(21) Appl. No.: 18/972,366

(22) Filed: Dec. 6, 2024

(51) Int. Cl. G01S 7/4863; G01S 7/481; H10F 30/225

(52) U.S. Cl. CPC G01S 7/4863; G01S 7/4816; H10F 30/225

(57) ABSTRACT

A light sensor includes an integrated circuit including an array of time-to-digital converters and an array of first interconnects connected to the array of time-to-digital converters. A plurality of single photon avalanche photodiode circuits include a second interconnect. Each of the plurality of single photon avalanche photodiode circuits corresponds to a single pixel. The plurality of single photon avalanche photodiode circuits are individually arranged on the integrated circuit with the second interconnect of the plurality of single photon avalanche photodiode circuits connected to a corresponding one of the first interconnects of the integrated circuit.

### INTRODUCTION

The information provided in this section is for the purpose of generally presenting the context of the disclosure. Work of the presently named inventors, to the extent it is described in this section, as well as aspects of the description that may not otherwise qualify as prior art at the time of filing, are neither expressly nor impliedly admitted as prior art against the present disclosure.

The present disclosure relates to light sensors, and more particularly to a light sensor including a single photon avalanche photodiode (SPAD) array formed using microassembly techniques.

Vehicles may include driver assistance controllers supporting fully or partially autonomous driving modes of the vehicle. These vehicles include one or more sensors such as radio detection and ranging (radar) sensors and/or light detection and ranging (lidar) sensors that output radio or light pulses, respectively, and receive reflected returns from objects in a vehicle path. In some examples, a receiver of the lidar sensors includes an array of single photon avalanche photodiodes (SPADs) that are monolithically formed on an integrated circuit.

### SUMMARY

A sensor includes an integrated circuit including an array of time-to-digital converters and an array of first interconnects connected to the array of time-to-digital converters. A plurality of single photon avalanche photodiode circuits include a second interconnect. Each of the plurality of single photon avalanche photodiode circuits corresponds to a single pixel. The plurality of single photon avalanche photodiode circuits are individually arranged on the integrated circuit with the second interconnect of the plurality of single photon avalanche photodiode circuits connected to a corresponding one of the first interconnects of the integrated circuit.

In other features, the plurality of single photon avalanche photodiode circuits are spaced on the integrated circuit with a fixed pitch. The plurality of single photon avalanche photodiode circuits are spaced on the integrated circuit with a variable pitch. The first interconnects and the second interconnect of the plurality of single photon avalanche photodiode circuits comprise hybrid copper interconnects. The integrated circuit further includes an interconnect layer.

In other features, the interconnect layer is arranged between the array of time-to-digital converters and the array of first interconnects. The sensor forms part of a receiver of a light detection and ranging sensor.

A sensor includes a backplane substrate. A plurality of integrated circuits includes a time-to-digital converter and a first interconnect providing a connection to the time-to-digital converter, each of the plurality of integrated circuits correspond to a single pixel. A plurality of single photon avalanche photodiode circuits include a second interconnect. Each of the plurality of single photon avalanche photodiode circuits corresponds to a single pixel. The plurality of single photon avalanche photodiode circuits are individually arranged on the plurality of integrated circuits with the second interconnect of the plurality of single photon avalanche photodiode circuits connected to a corresponding one of the first interconnect of the integrated circuit. The plurality of integrated circuits are arranged on the backplane substrate.

In other features, the plurality of single photon avalanche photodiode circuits and the plurality of integrated circuits are spaced on the backplane substrate with a fixed pitch. The plurality of single photon avalanche photodiode circuits and the plurality of integrated circuits are spaced on the backplane substrate with a variable pitch. The first interconnect and the second interconnect include hybrid copper interconnects. The plurality of integrated circuits further include an interconnect layer. The interconnect layer is arranged between the time-to-digital converter and the first interconnect.

In other features, the backplane substrate is one of planar and nonplanar. The sensor forms part of a receiver of a light detection and ranging sensor.

A vehicle includes a light detection and ranging sensor comprising an integrated circuit including an array of time-to-digital converters and an array of first interconnects connected to the array of time-to-digital converters. A plurality of single photon avalanche photodiode circuits each including a second interconnect. Each of the plurality of single photon avalanche photodiode circuits corresponds to a single pixel. The plurality of single photon avalanche photodiode circuits are individually arranged on the integrated circuit with the second interconnect of the plurality of single photon avalanche photodiode circuits connected to a corresponding one of the first interconnects of the integrated circuit. A controller including an autonomous driving module configured to support at least one of partially or fully autonomous driving in response to the light detection and ranging sensor.

In other features, the plurality of single photon avalanche photodiode circuits are spaced on the integrated circuit with a fixed pitch. The plurality of single photon avalanche photodiode circuits are spaced on the integrated circuit with a variable pitch. The first interconnects and the second interconnect of the plurality of single photon avalanche photodiode circuits include hybrid copper interconnects.

In other features, the integrated circuit further includes an interconnect layer. The interconnect layer is arranged between the array of time-to-digital converters and the array of first interconnects.

Further areas of applicability of the present disclosure will become apparent from the detailed description, the claims, and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 is a functional block diagram of an example of a vehicle including a light detection and ranging (lidar) sensor according to the present disclosure;

FIG. 2A is a side cross section of an example of a substrate including a plurality of single photon avalanche photodiode (SPAD) pixels;

FIG. 2B is a side cross section of an example the SPAD pixels after dicing according to the present disclosure;

FIG. 2C is a side cross section of an example of the SPAD pixel according to the present disclosure;

FIG. 3 is a side cross section of an example of a substrate including an integrated circuit including a time to digital circuit array and an interconnect layer according to the present disclosure;

FIG. 4 is a side cross section of an example of the substrate of FIG. 3 with the SPAD pixels attached with a fixed pitch using a microassembly process according to the present disclosure;

FIG. 5 is a side cross section of an example of the substrate of FIG. 3 with the SPAD pixels attached with a variable pitch using a microassembly process according to the present disclosure;

FIG. 6 is a side cross section of an example of SPAD pixels mounted on respective time-to-digital (TDC) integrated circuits (ICs) and arranged on a planar backplane substrate according to the present disclosure;

FIG. 7 is a side cross section of an example of SPAD pixels mounted on respective TDC integrated circuits and arranged on a curved backplane substrate according to the present disclosure; and

FIGS. 8A and 8B are examples of methods for fabricating SPAD arrays according to the present disclosure.

In the drawings, reference numbers may be reused to identify similar and/or identical elements.

### DETAILED DESCRIPTION

While the following description relates to a light detection and imaging (lidar) sensor for a vehicle, the lidar sensor can be used in stationary or other types of applications.

Some lidar sensors include a monolithically formed substrate including a SPAD array. The SPAD array includes a plurality of single photon avalanche photodiode (SPAD) macro pixels (or pixels). Each of the SPAD pixels may include sub-pixels (or micro-pixels). In some examples, each of the SPAD pixels is associated with a time-to-digital converter (TDC) (e.g., nominally one TDC per SPAD macro-pixel). The substrate includes an array of contacts (corresponding to each of the SPAD pixels) that are bonded and optionally annealed to contacts of a monolithic integrated circuit (IC) including a time-to-digital converter for each SPAD pixel.

The physical size of the time-to-digital converter (TDC) for each pixel is larger than the SPAD pixel, which complicates the development of high-resolution SPAD arrays. The unique approach described herein decouples the dimensional constraints of the SPAD array and TDC IC using microassembly techniques. As a result, higher resolution (e.g., higher pixel count) SPAD arrays can be manufactured.

Individual SPAD pixels are fabricated and diced. The SPAD pixels are placed, bonded, and optionally annealed to the TDC IC using microassembly techniques. This approach enables high-resolution arrays and allows for the generation of non-uniform SPAD arrays that compensates for optical distortion. This approach enables greater optimization for maintaining resolution across a field of view in lidar applications. Forming SPAD arrays using microassembly processes also provides a more rapid path to custom array configurations by avoiding the up-to 1.5 year period required for design, layout, and fabrication of custom monolithic SPAD arrays.

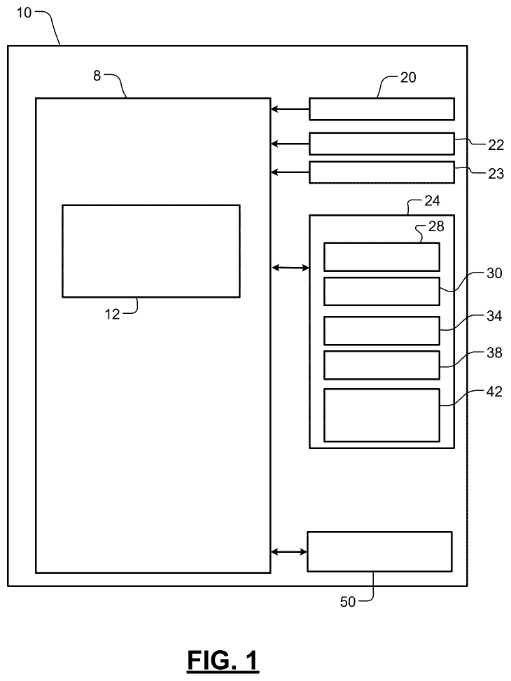

Referring now to FIG. 1, a vehicle 10 includes a controller 8 including an autonomous driving module 12 configured to support fully and/or partially autonomous driving modes based on data captured by a light detection and ranging (lidar) sensor 24, one or more radar sensors 22, and/or one or more cameras 23.

The lidar sensor 24 optionally includes one or more scanners 28, one or more lasers 30, and one or more single photon avalanche photodiode (SPAD) arrays including SPAD pixels. In some examples, the laser 30 includes one or more vertical cavity surface emitting lasers (VCSELs). In some examples, the VCSELs are operated in a flash mode without a scanner. The lidar sensor 24 further includes a time-to-digital converter (TDC) IC 38 configured to determine an elapsed time from the generation of the light pulses to the returns. The lidar sensor 24 optionally includes a point cloud generator/storage 42 configured to store a point cloud based on the returns. In some examples, the data from the lidar sensor 24 and/or other controllers are used to generate an obstacle grid including object data in the path of the vehicle 10. In some examples, the lidar sensor 24 measures calibrated target reflectivity for each return.

The vehicle 10 may further include a global positioning system/compass 20 configured to provide GPS coordinates and/or vehicle orientation. The vehicle 10 may further include a radio detection and ranging (radar) system 22 configured to generate radio signals and to receive the returns. The vehicle 10 includes control inputs 50 such as a steering wheel, an accelerator pedal, a brake pedal, turn signals, etc.

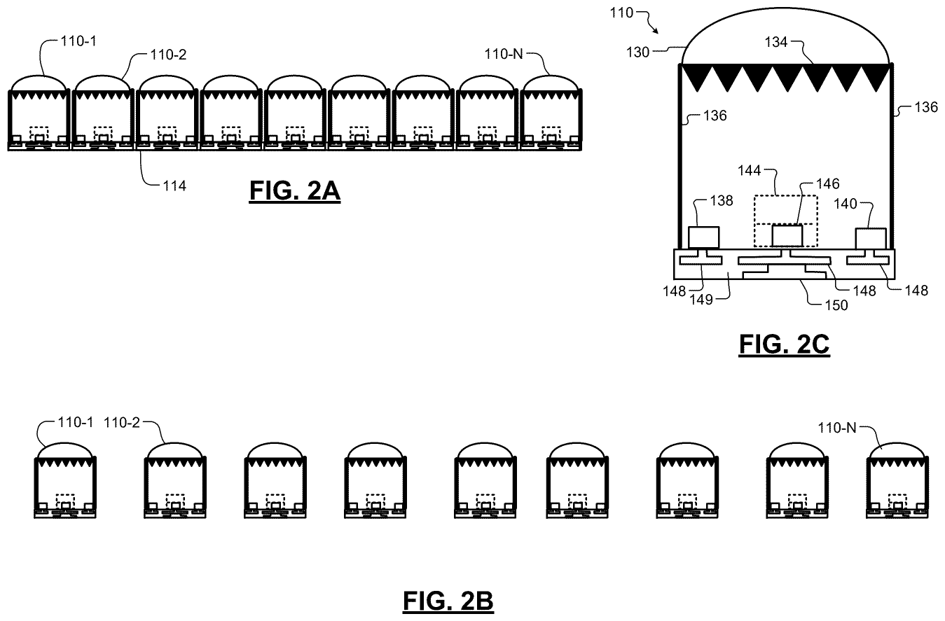

Referring now to FIGS. 2A to 2C, a substrate 114 is fabricated to include a plurality of single photon avalanche photodiode (SPAD) pixels 110-1, 110-2, . . . , 110-N (collectively SPAD pixels 110). While a single row is shown in FIG. 2A, the SPAD pixels 110 can be arranged in an array of M×N pixels where M and N are integers greater than zero.

In FIG. 2B, the SPAD pixels 110-1, 110-2, . . . , 110-N are separated into individual SPAD pixels 110-1, 110-2, . . . , 110-N. The individual SPAD pixels 110-1, 110-2, . . . , 110-N are separated or diced using established wafer dicing techniques (mechanical, laser, etc.) into single SPAD pixels 110 and loaded into a cartridge or other carrier compatible with a microassembly process.

In FIG. 2C, the SPAD pixel 110 includes a lens 130 and light guiding portions 134 that direct lidar returns between side walls 136 onto an avalanche area 144 arranged above an n+ region 146 that is located between p+ regions 138 and 140 of diodes. Contacts 148 arranged in an insulating layer 149 are made of a conducting material and are connected to the n+ region 146 and/or the p+ regions 138 and 140. One or more contact pads 150 connect the contacts 148 of one or more of the n+ region 146 and/or the p+regions 138 and 140 to the TDC IC.

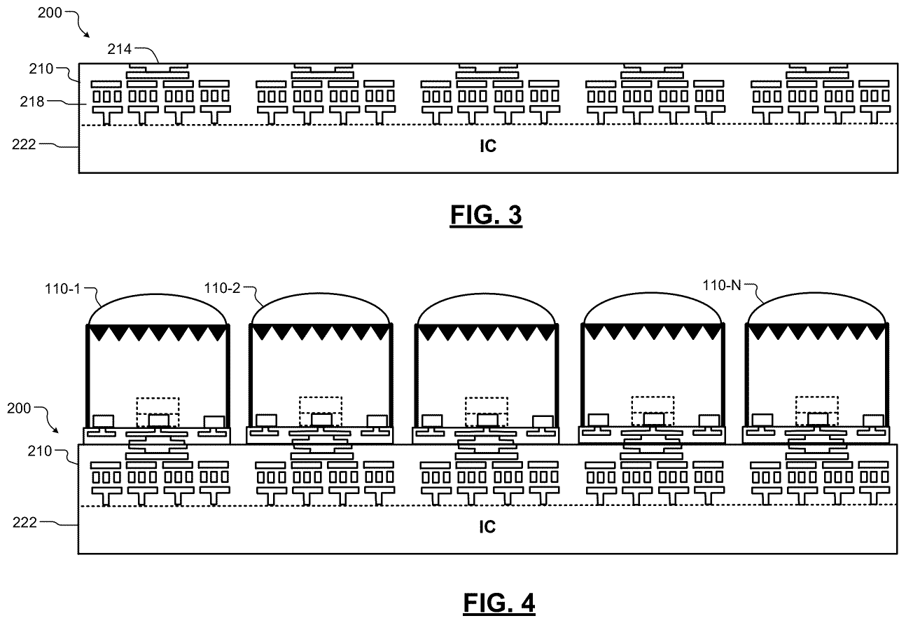

Referring now to FIG. 3, a substrate 200 includes a TDC IC 222 including a TDC array and/or the point cloud generator/storage. An interconnect layer 210 is arranged on one side of the TDC IC 222 and includes contact pads 214 to connect to the contact pads 150 of the SPAD pixels 110. In some examples, the contact pads 214 and 150 include hybrid-copper interconnects. In some examples, one or both of the contact pads 214 and 150 are made of copper and surrounded by a dielectric layer (e.g., an oxide layer such as silicon oxide (SiO₂)) prior to microassembly and annealing.

In some examples, a plurality of the individual SPAD pixels are connected to a single digital logic IC using a fixed or variable pitch. In some examples, a plurality of the individual SPAD pixels are connected to individual TDC ICs and then mounted on a backplane substrate using a fixed or variable pitch. The individual digital logic ICs can be fabricated in a manner similar to the individual SPAD pixels (fabrication of an array followed by dicing of individual TDC ICs).

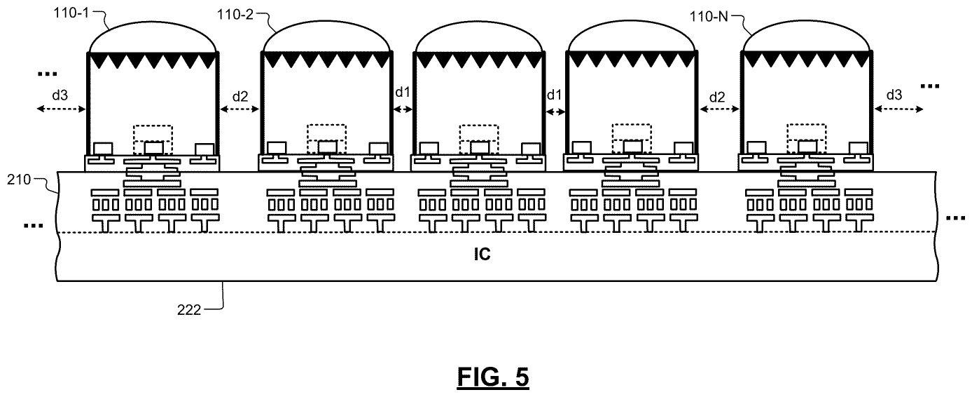

Referring now to FIG. 4, the substrate 200 of FIG. 3 is shown with the SPAD pixels 110 arranged with a fixed pitch (d₁) using a microassembly process. After microassembly, an annealing step can be performed to strengthen the bond connecting the contact pads 214 and 150.

Referring now to FIG. 5, the substrate 200 of FIG. 3 is shown with the SPAD pixels 110 arranged with a variable pitch (e.g., d₁<d₂<d₃ . . . , d₁>d₂>d₃ . . . , or other patterns) using a microassembly process. In this example, the pitch increases from the center to the edge of the SPAD array. However, other variable pitch patterns can be used. After microassembly, an annealing step can be performed to strengthen the bond connecting the contact pads 214 and 150.

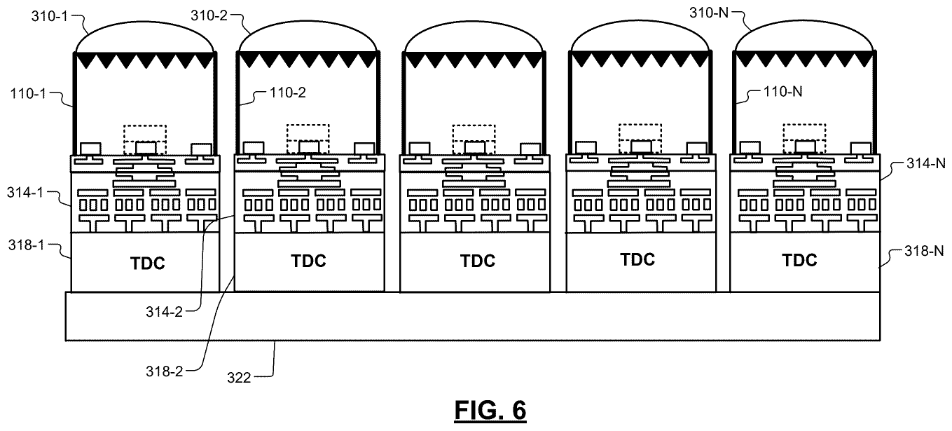

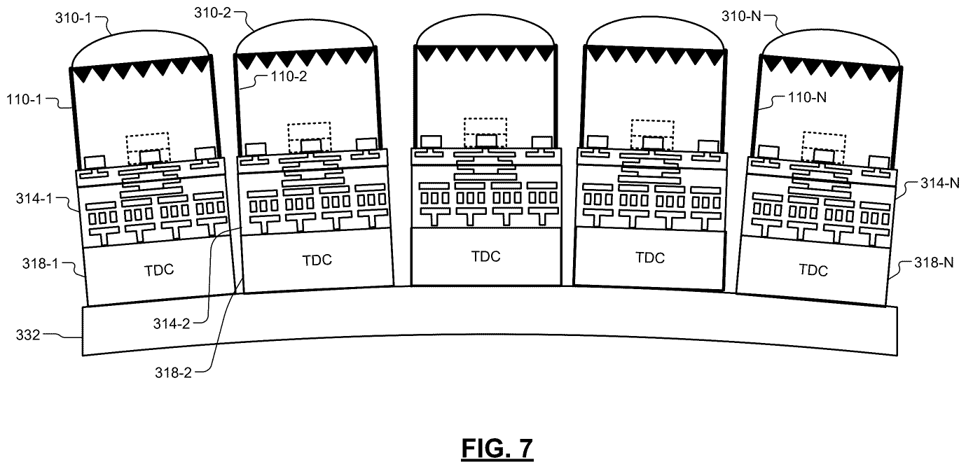

Referring now to FIGS. 6 and 7, the SPAD pixels and the TDC ICs can be fabricated on a substrate and then diced as described above to form individual SPAD pixels and TDC circuits 310-1, 310-2, . . . , and 310-N. The SPAD pixels and TDC ICs 310-1, 310-2, . . . , and 310-N include interconnect layer 314-1, 314-2, . . . , and 314-N and a TDC layer 318-1, 318-2, . . . , and 318-N, respectively. The SPAD pixels and TDC ICs 310-1, 310-2, . . . , and 310-N are arranged on a planar backplane substrate 322. In FIG. 7, the SPAD pixels and TDC ICs 310-1, 310-2, . . . , and 310-N are arranged on a curved backplane substrate 332 to compensate for optical distortion.

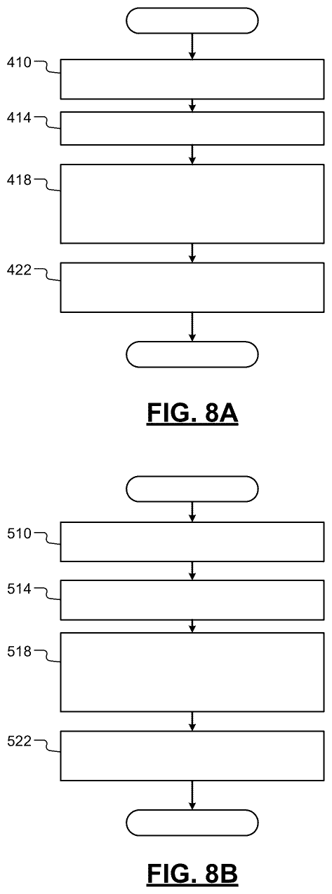

Referring now to FIGS. 8A and 8B, examples of methods for fabricating a SPAD arrays are shown. In FIG. 8A, a plurality of SPAD pixels are fabricated on a substrate at 410. At 414, the SPAD pixels are diced to separate individual pixels. At 418, the SPAD pixels are placed on a substrate including an interconnect layer and digital logic circuit(s) (e.g., the TDC ICs and/or the point cloud storage). At 422, annealing is optionally performed to strengthen the bonds.

In FIG. 8B, a plurality of SPAD pixels, interconnects, and TDC ICs are fabricated on a substrate at 510. At 514, the SPAD pixels, interconnects, and TDC ICs are diced to separate individual SPAD pixels, interconnects, and TDC ICs. At 518, the SPAD pixels, interconnects, and ICs are placed on a backplane substrate. At 522, annealing is optionally performed to strengthen the bonds.

While the foregoing description relates to a light sensor used in a receiver of a lidar sensor, the light sensor can also be used for near infrared imaging as well.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In the figures, the direction of an arrow, as indicated by the arrowhead, generally demonstrates the flow of information (such as data or instructions) that is of interest to the illustration. For example, when element A and element B exchange a variety of information but information transmitted from element A to element B is relevant to the illustration, the arrow may point from element A to element B. This unidirectional arrow does not imply that no other information is transmitted from element B to element A. Further, for information sent from element A to element B, element B may send requests for, or receipt acknowledgements of, the information to element A.

In this application, including the definitions below, the term “module” or the term “controller” may be replaced with the term “circuit.” The term “module” may refer to, be part of, or include: an Application Specific Integrated Circuit (ASIC); a digital, analog, or mixed analog/digital discrete circuit; a digital, analog, or mixed analog/digital integrated circuit; a combinational logic circuit; a field programmable gate array (FPGA); a processor circuit (shared, dedicated, or group) that executes code; a memory circuit (shared, dedicated, or group) that stores code executed by the processor circuit; other suitable hardware components that provide the described functionality; or a combination of some or all of the above, such as in a system-on-chip.

The module may include one or more interface circuits. In some examples, the interface circuits may include wired or wireless interfaces that are connected to a local area network (LAN), the Internet, a wide area network (WAN), or combinations thereof. The functionality of any given module of the present disclosure may be distributed among multiple modules that are connected via interface circuits. For example, multiple modules may allow load balancing. In a further example, a server (also known as remote, or cloud) module may accomplish some functionality on behalf of a client module.

The term code, as used above, may include software, firmware, and/or microcode, and may refer to programs, routines, functions, classes, data structures, and/or objects. The term shared processor circuit encompasses a single processor circuit that executes some or all code from multiple modules. The term group processor circuit encompasses a processor circuit that, in combination with additional processor circuits, executes some or all code from one or more modules. References to multiple processor circuits encompass multiple processor circuits on discrete dies, multiple processor circuits on a single die, multiple cores of a single processor circuit, multiple threads of a single processor circuit, or a combination of the above. The term shared memory circuit encompasses a single memory circuit that stores some or all code from multiple modules. The term group memory circuit encompasses a memory circuit that, in combination with additional memories, stores some or all code from one or more modules.

The term memory circuit is a subset of the term computer-readable medium. The term computer-readable medium, as used herein, does not encompass transitory electrical or electromagnetic signals propagating through a medium (such as on a carrier wave); the term computer-readable medium may therefore be considered tangible and non-transitory. Non-limiting examples of a non-transitory, tangible computer-readable medium are nonvolatile memory circuits (such as a flash memory circuit, an erasable programmable read-only memory circuit, or a mask read-only memory circuit), volatile memory circuits (such as a static random access memory circuit or a dynamic random access memory circuit), magnetic storage media (such as an analog or digital magnetic tape or a hard disk drive), and optical storage media (such as a CD, a DVD, or a Blu-ray Disc).

The apparatuses and methods described in this application may be partially or fully implemented by a special purpose computer created by configuring a general purpose computer to execute one or more particular functions embodied in computer programs. The functional blocks, flowchart components, and other elements described above serve as software specifications, which can be translated into the computer programs by the routine work of a skilled technician or programmer.

The computer programs include processor-executable instructions that are stored on at least one non-transitory, tangible computer-readable medium. The computer programs may also include or rely on stored data. The computer programs may encompass a basic input/output system (BIOS) that interacts with hardware of the special purpose computer, device drivers that interact with particular devices of the special purpose computer, one or more operating systems, user applications, background services, background applications, etc.

The computer programs may include: (i) descriptive text to be parsed, such as HTML (hypertext markup language), XML (extensible markup language), or JSON (JavaScript Object Notation) (ii) assembly code, (iii) object code generated from source code by a compiler, (iv) source code for execution by an interpreter, (v) source code for compilation and execution by a just-in-time compiler, etc. As examples only, source code may be written using syntax from languages including C, C++, C #, Objective-C, Swift, Haskell, Go, SQL, R, Lisp, Java®, Fortran, Perl, Pascal, Curl, OCaml, Javascript®, HTML5 (Hypertext Markup Language 5th revision), Ada, ASP (Active Server Pages), PHP (PHP: Hypertext Preprocessor), Scala, Eiffel, Smalltalk, Erlang, Ruby, Flash®, Visual Basic®, Lua, MATLAB, SIMULINK, and Python®.

What is claimed is

1. A sensor comprising:
an integrated circuit including:
an array of time-to-digital converters; and
an array of first interconnects connected to the array of time-to-digital converters; and
a plurality of single photon avalanche photodiode circuits each including a second interconnect,
wherein each of the plurality of single photon avalanche photodiode circuits corresponds to a single pixel,
wherein the plurality of single photon avalanche photodiode circuits are individually arranged on the integrated circuit with the second interconnect of the plurality of single photon avalanche photodiode circuits connected to a corresponding one of the first interconnects of the integrated circuit.

2. The sensor of claim 1, wherein the plurality of single photon avalanche photodiode circuits are spaced on the integrated circuit with a fixed pitch.

3. The sensor of claim 1, wherein the plurality of single photon avalanche photodiode circuits are spaced on the integrated circuit with a variable pitch.

4. The sensor of claim 1, wherein the first interconnects and the second interconnect of the plurality of single photon avalanche photodiode circuits comprise hybrid copper interconnects.

5. The sensor of claim 1, wherein the integrated circuit further includes an interconnect layer.

6. The sensor of claim 5, wherein the interconnect layer is arranged between the array of time-to-digital converters and the array of first interconnects.

7. The sensor of claim 1, wherein the sensor forms part of a receiver of a light detection and ranging sensor.

8. A light sensor comprising:
a backplane substrate;
a plurality of integrated circuits each including:
a time-to-digital converter; and
a first interconnect providing a connection to the time-to-digital converter, each of the plurality of integrated circuits correspond to a single pixel; and
a plurality of single photon avalanche photodiode circuits each including a second interconnect, each of the plurality of single photon avalanche photodiode circuits corresponding to a single pixel,
wherein the plurality of single photon avalanche photodiode circuits are individually arranged on the plurality of integrated circuits with the second interconnect of the plurality of single photon avalanche photodiode circuits connected to a corresponding one of the first interconnect of the integrated circuit, and
wherein the plurality of integrated circuits are arranged on the backplane substrate.

9. The sensor of claim 8, wherein the plurality of single photon avalanche photodiode circuits and the plurality of integrated circuits are spaced on the backplane substrate with a fixed pitch.

10. The sensor of claim 8, wherein the plurality of single photon avalanche photodiode circuits and the plurality of integrated circuits are spaced on the backplane substrate with a variable pitch.

11. The sensor of claim 8, wherein the first interconnect and the second interconnect include hybrid copper interconnects.

12. The sensor of claim 8, wherein the plurality of integrated circuits further include an interconnect layer.

13. The sensor of claim 12, wherein the interconnect layer is arranged between the time-to-digital converter and the first interconnect.

14. The sensor of claim 8, wherein the backplane substrate is one of planar and nonplanar.

15. The sensor of claim 8, wherein the sensor forms part of a receiver of a light detection and ranging sensor.

16. A vehicle including:
a light detection and ranging sensor comprising:
an integrated circuit including an array of time-to-digital converters and an array of first interconnects connected to the array of time-to-digital converters; and
a plurality of single photon avalanche photodiode circuits each including a second interconnect,
wherein each of the plurality of single photon avalanche photodiode circuits corresponds to a single pixel,
wherein the plurality of single photon avalanche photodiode circuits are individually arranged on the integrated circuit with the second interconnect of the plurality of single photon avalanche photodiode circuits connected to a corresponding one of the first interconnects of the integrated circuit; and
a controller including an autonomous driving module configured to support at least one of partially or fully autonomous driving in response to the light detection and ranging sensor.

17. The vehicle of claim 16, wherein the plurality of single photon avalanche photodiode circuits are spaced on the integrated circuit with a fixed pitch.

18. The vehicle of claim 16, wherein the plurality of single photon avalanche photodiode circuits are spaced on the integrated circuit with a variable pitch.

19. The vehicle of claim 16, wherein the first interconnects and the second interconnect of the plurality of single photon avalanche photodiode circuits include hybrid copper interconnects.

20. The vehicle of claim 16, wherein:
the integrated circuit further includes an interconnect layer, and
the interconnect layer is arranged between the array of time-to-digital converters and the array of first interconnects.
